(19) United States
(12) Patent Application Publication
(10) Pub. No.: US 2013/0082329 A1
(43) Pub. Date: Apr. 4, 2013

(54) MULTI-GATE FIELD-EFFECT TRANSISTORS WITH VARIABLE FIN HEIGHTS

(71) Applicants: Hsueh-Chung Chen, Cohoes, NY (US); Su Chen Fan, Cohoes, NY (US); Theodorus E. Standaert, Clifton Park, NY (US); Chun-Chen Yeh, Clifton Park, NY (US)

(72) Inventors: Hsueh-Chung Chen, Cohoes, NY (US); Su Chen Fan, Cohoes, NY (US); Theodorus E. Standaert, Clifton Park, NY (US); Chun-Chen Yeh, Clifton Park, NY (US)

(73) Assignee: INTERNATIONAL BUSINESS MACHINES CORPORATION, Armonk, NY (US)

(21) Appl. No.: 13/251,815

(22) Filed: Oct. 3, 2011

(51) Int. Cl. H01L 27/088; H01L 21/28; H01L 29/78

(52) U.S. Cl. 257/347; 438/585; 257/E29.255; 257/E27.06; 257/E21.19

(57) ABSTRACT

Multi-gate devices and methods of their fabrication are disclosed. A multi-gate device can include a gate structure and a plurality of fins. The gate structure envelops a plurality of surfaces of the fins, which are directly on a substrate that is composed of a semiconducting material. Each of the fins provides a channel between a respective source and a respective drain, is composed of the semiconducting material and is doped. A first fin of the plurality of fins has a first height that is different from a second height of a second fin of the plurality of fins such that drive currents of the first and second fins are different. Further, the first and second fins form a respective cohesive structure of the semiconducting material with the substrate. In addition, surfaces of the substrate that border the fins are disposed at a same vertical position.

### BACKGROUND

1. Technical Field

The present invention relates to semiconductor devices, and more particularly, to multi-gate field-effect transistor devices and fabrication methods.

2. Description of the Related Art

Throughout the evolution and advancement of computing devices, reducing their size and their power consumption while maintaining or improving a high processing capacity have long been design goals. Planar field-effect transistor (FET) devices, which have been widely used in integrated circuits for the past several decades, were found to be increasingly inefficient on the nanometer scale. Reducing the size of the channel between the terminals of planar transistors to this scale leads to an inefficient leakage of current in the off-state of the transistor, resulting in an increase in power consumption in its idle state. Multi-gate field-effect transistors (MuGFET) have been developed to address this problem, as they incorporate several gates that surround the channel between a source and drain terminal of the transistor on a plurality of surfaces, thereby enabling the suppression of leakage current in the off-state.

There are several different types of multi-gate devices. FinFETs and Trigate devices are two examples. FinFET devices include a thin fin, which can be made of silicon, that provides the channel between a source and a drain. The fin can be overlaid with one or more pairs of gates, where the gates in a pair are on opposing sides of the fin. Trigates are similar to FinFETs in that they also employ fins. However, in a Trigate device, two vertical gates respectively envelope two separate fins and a single top gate is overlaid on the two vertical gates. The top gate usually extends across a plurality of transistor cells in Trigate devices.

### SUMMARY

One embodiment is directed to a multi-gate device that includes a gate structure and a plurality of fins. The gate structure envelops a plurality of surfaces of the fins, which are directly on a substrate that is composed of a semiconducting material. Each of the fins provides a channel between a respective source and a respective drain, is composed of the semiconducting material and is doped. A first fin of the plurality of fins has a first height that is different from a second height of a second fin of the plurality of fins such that drive currents of the first and second fins are different. Further, the first and second fins form a respective cohesive structure of the semiconducting material with the substrate. In addition, surfaces of the substrate that border the first fin and surfaces of the substrate that border the second fin are disposed at a same vertical position.

An alternative embodiment is directed to a circuit apparatus including a plurality of multi-gate devices that include a first gate structure, a second gate structure and a plurality of fins that are directly on a substrate that is composed of a semiconducting material. The first gate structure envelops a plurality of surfaces of a first subset of the plurality of fins and the second gate structure envelops a plurality of surfaces of a second subset of the plurality of fins. Each fin of the plurality of fins provides a channel between a respective source and a respective drain, is composed of the semiconducting material and is doped. A first fin of the plurality of fins has a first height that is different from a second height of a second fin of the plurality of fins such that drive currents of the first and second fins are different. Moreover, the first and second fins form a respective cohesive structure of the semiconducting material with the substrate. Additionally, the surfaces of the substrate that border the first fin and the surfaces of the substrate that border the second fin are disposed at a same vertical position.

Another embodiment is directed to a method for fabricating a circuit apparatus. In accordance with the method, at least one recess is formed in a substrate that is composed of a semiconducting material such that a difference between a depth of the at least one recess and a height of a surface of the substrate effects differences in height between fins of a plurality of fins. In addition, the substrate is etched to form the plurality of fins, wherein a first fin of the plurality of fins has a first height that is different from a second height of a second fin of the plurality of fins such that drive currents of the first and second fins are different. Further, the first and second fins form a respective cohesive structure of the semiconducting material with the substrate. The surfaces of the substrate that border the first fin and the surfaces of the substrate that border the second fin are disposed at a same vertical position. The method further comprises forming a gate structure over a plurality of surfaces of a first subset of the plurality of fins.

These and other features and advantages will become apparent from the following detailed description of illustrative embodiments thereof, which is to be read in connection with the accompanying drawings.

### BRIEF DESCRIPTION OF DRAWINGS

The disclosure will provide details in the following description of preferred embodiments with reference to the following figures wherein:

FIG. 1 is block diagram of an exemplary circuit in accordance with the present principles;

FIG. 2 is a block diagram of an exemplary circuit in which multi-gate devices have a consistent fin height;

FIG. 3 is a block diagram of an exemplary embodiment of a FinFET device;

FIG. 4 is a block diagram of an exemplary embodiment of an alternative FinFET device;

FIG. 5 is a block diagram of an exemplary embodiment of an alternative FinFET device;

FIG. 6 is a block diagram of a semiconducting substrate at a preliminary stage of a method for fabricating multi-gate devices in accordance with an exemplary embodiment;

FIG. 7 is a block diagram of a semiconducting substrate at an intermediate stage of a method for fabricating multi-gate devices in accordance with an exemplary embodiment;

FIG. 8 is a block diagram of a semiconducting substrate at an intermediate stage of a method for fabricating multi-gate devices in accordance with an exemplary embodiment;

FIG. 9 is a block diagram of a semiconducting substrate at an intermediate stage of a method for fabricating multi-gate devices in accordance with an exemplary embodiment;

FIG. 10 is a block diagram of fins on a semiconducting substrate at an intermediate stage of a method for fabricating multi-gate devices in accordance with an exemplary embodiment;

FIG. 11 is a block diagram of fins on a semiconducting substrate at an oxide deposition stage of a method for fabricating multi-gate devices in accordance with an exemplary embodiment;

FIG. 12 is a block diagram of partially formed multi-gate devices at an intermediate stage of a method for fabricating multi-gate devices in accordance with an exemplary embodiment;

FIG. 13 is a block diagram of multi-gate devices fabricated in accordance with an exemplary embodiment;

FIG. 14 is a block diagram of an exemplary embodiment of an alternative FinFET device;

FIG. 15 is a block diagram of an exemplary embodiment of an alternative FinFET device; and

FIG. 16 is a block/flow diagram of an exemplary embodiment of a method for fabricating multi-gate devices and a circuit in accordance with an exemplary embodiment.

### DETAILED DESCRIPTION OF PREFERRED EMBODIMENTS

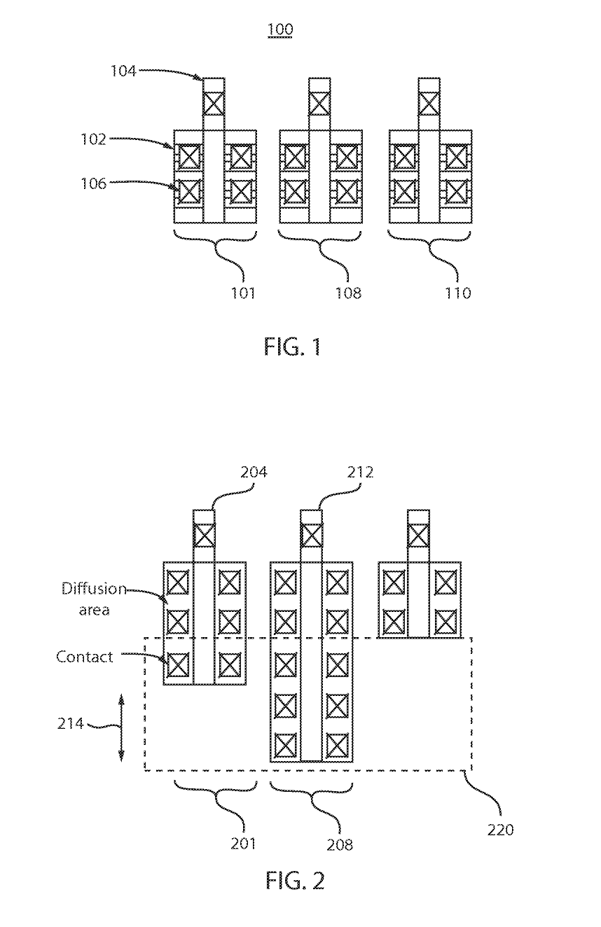

In addition to the benefit of suppressing leakage current described above, another advantage of multi-gate devices is that the drive current of the devices can be altered without affecting the layout area occupied by the device on an integrated circuit. For example, referring now to the drawings in which like numerals represent the same or similar elements and initially to FIG. 1, a first implementation 100 of a circuit including FinFET devices is illustrated. Each of the devices 101 includes fins 102, a gate 104 and contacts 106. Assume that it is desirable for the drive current for two of the FinFET devices to be modified. The drive current is an important design parameter, as an improper drive current can damage elements of a circuit. The traditional means of controlling the drive current, as in planar devices, is to adjust the width of the gate. For example, referring to FIG. 2, with continuing reference to FIG. 1, the widths of the gates of device 101 and 108 can be extended in the y-direction 214, as illustrated by gates 204 and 212 of the corresponding devices 201 and 208, to alter the drive current. However, this alteration would require the use of larger chip area 220, thereby limiting the space that can be utilized for other elements of the circuit. One benefit of FinFETs is that the drive current can be adjusted by modifying the height of the fins in the z-direction (in and out of the plane of the drawing views in FIGS. 1 and 2). In particular, an integrated circuit can be fabricated to have FinFET devices that occupy the same chip area as devices 101 and 108 of FIG. 1 but have the drive current of devices 201 and 208 of FIG. 2 by configuring the devices to have different fin heights.

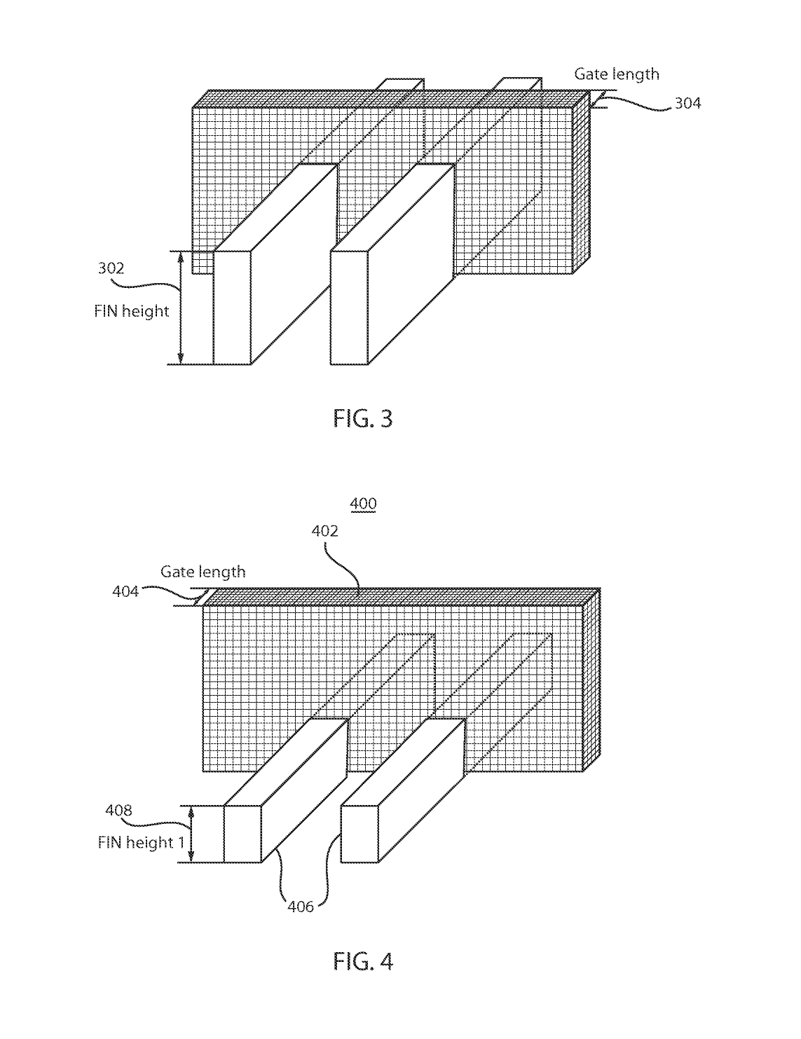

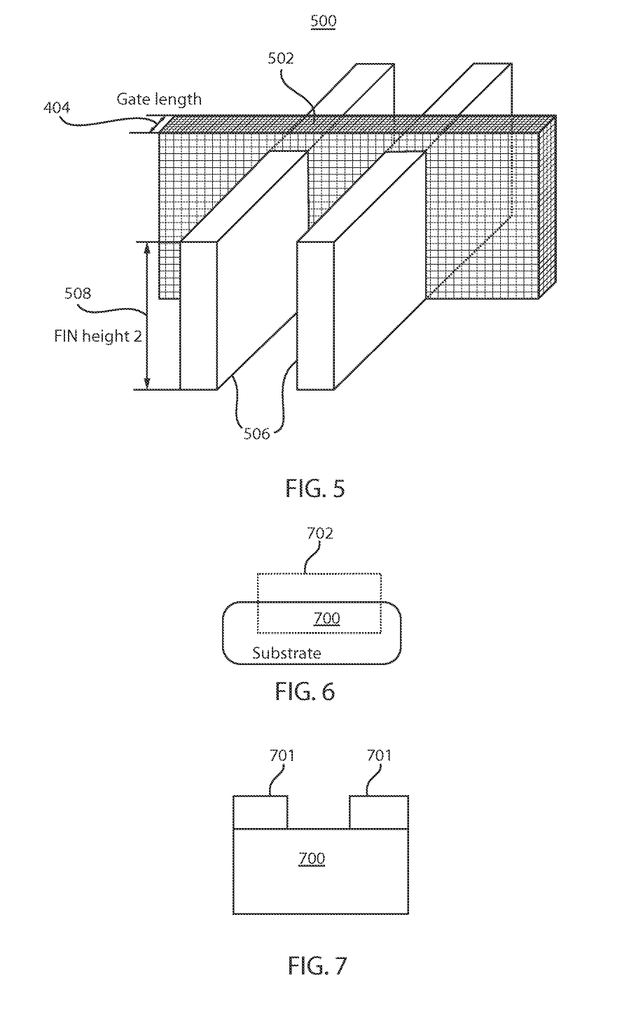

For example, referring to FIGS. 3-5, the drive current of a FinFET device is dependent on the fin height 302, gate length 304 and number of fins. Thus, the drive current can be modified by altering the fin height and retaining the same gate length and number of FinFET devices. For example, the device 400 can include a gate 402 with a gate length 404 and fins 406 with a first height 408, while the device 500, which can be on the same chip as device 400 and can share the same gate as device 400, can include a gate 502 with the gate length 404 and fins 506 with a second height 508. Here, the fin height 508 is larger than the fin height 408, thereby effecting a larger drive current, and a larger capacitance, for the device 500 as compared to the drive current, and capacitance, of the device 400. It can be shown that, by extending the fin heights of multi-gate devices, the drive current can be increased by two times for n-type devices and seven times for p-type devices as compared to drive currents of multi-gate devices with consistent fin heights. As a result, multi-gate devices that have multiple, different fin heights can be employed to meet drive current specifications on a chip, while retaining the same circuit area layout footprint.

Although multi-gate devices provide several benefits, they are generally expensive to fabricate. Thus, to adequately exploit the controllability of the drive current of multi-gate devices through fin height modifications, a manufacturing process that minimizes costs associated with the fabrication of such devices should be employed. Embodiments of the present invention provide an efficient means for fabricating multi-gate devices with various fin heights by adapting processes and equipment designed for the manufacture of multi-gate devices with consistent fin heights on a bulk semiconductor substrate. In particular, embodiments of the present invention fabricate multi-gate devices with various fin heights in a way that minimally modifies these processes. For example, one way of adapting these processes to manufacture multi-gate devices with different fin heights is modifying photoresist patterns or adding etching steps in the middle of the fabrication process. However, such modifications increase the complexity and cost of the process. In contrast, the exemplary embodiments of the present invention can reuse elements of these processes by implementing novel pre-processing steps before such processes are performed, thereby permitting reuse of the processes in essentially their original form to fabricate multi-gate devices with varying heights. For example, exemplary embodiments can implement these processes as is, without affecting photoresist patterns used or interrupting such processes with additional etches. The preprocessing performed in accordance with the present principles can be exhibited by the structure of the fins formed, where fins of various heights form a respective cohesive structure with a semiconducting substrate and where surfaces of the substrate that border the fins are disposed at a common vertical position. While this structure may be different from structures fabricated in accordance with methods that significantly modify height-consistent fabrication processes, it provides the same or more advantageous benefits associated with the utilization of varying fin heights. Thus, because embodiments can employ processes designed for fabricating multi-gate devices with consistent fin heights on a bulk semiconductor with minimal modifications, the implementation of multi-gate devices with variable fin heights can be achieved with minimal cost and complexity.

As will be appreciated by one skilled in the art, aspects of the present invention may be embodied as a system, method, device or apparatus. Aspects of the present invention are described below with reference to flowchart illustrations and/or block diagrams of methods, apparatus (systems) and devices according to embodiments of the invention. The flowchart and block diagrams in the Figures illustrate the architecture, functionality, and operation of possible implementations of methods, apparatus (systems) and devices according to various embodiments of the present invention. It should also be noted that, in some alternative implementations, the functions noted in the block may occur out of the order noted in the figures. For example, two blocks shown in succession may, in fact, be performed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose systems that perform the specified functions or acts.

It is to be understood that the present invention will be described in terms of a given illustrative architecture having a substrate; however, other architectures, structures, substrate materials and process features and steps may be varied within the scope of the present invention.

It will also be understood that when an element described as a layer, region or substrate is referred to as being “on” or “over” another element, it can be directly on the other element or intervening elements may also be present. In contrast, when an element is referred to as being “directly on” or “directly over” another element, there are no intervening elements present. Similarly, it will also be understood that when an element described as a layer, region or substrate is referred to as being “beneath” or “below” another element, it can be directly beneath the other element or intervening elements may also be present. In contrast, when an element is referred to as being “directly beneath” or “directly below” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A design for an integrated circuit chip including multi-gate devices of the present principles may be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer may transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

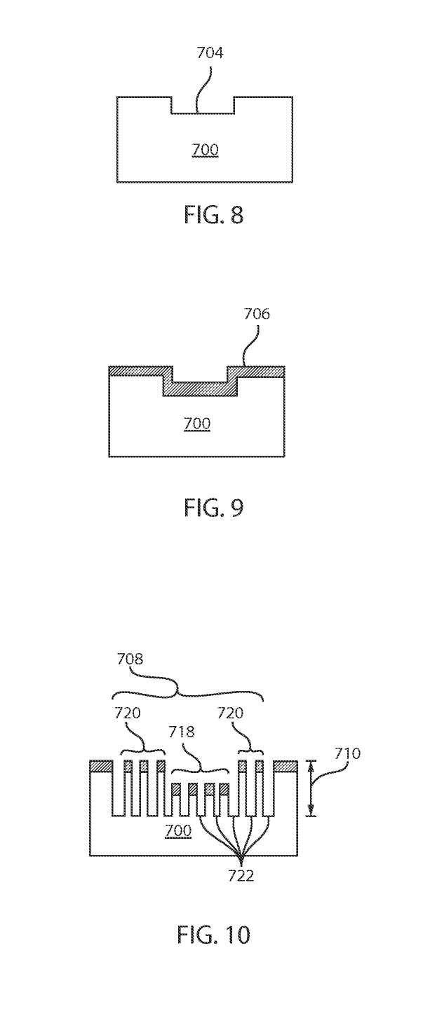

Referring now to FIGS. 6-13, a set of processing stages in the fabrication of multi-gate devices in accordance with an exemplary implementation of the present principles is illustrated. FIG. 6 depicts a substrate 700 in which the multi-gate devices can be formed. Here, the substrate can be a bulk semiconductor substrate, such as silicon. Bulk substrates are preferable over silicon on insulator (SOI) substrates, as a much wider variety of fin heights are achievable on a single device, thereby enabling a significantly larger controllability of the drive currents, as bulk substrates are not limited by the size of the SOI layer. In addition, it should be understood that the substrate 700 may include any suitable material and is not limited to a silicon substrate. For example, substrate 700 may include Gallium Arsenide, monocrystalline silicon, Germanium, or any other material or combination of materials where the present principles may be applied. In some embodiments, the substrate 700 further comprises other features or structures that are formed on or in the semiconductor substrate in previous process steps. It should be noted that the illustrations in FIGS. 7-13 depict fabrication of the multi-gate devices in the region 702 of the substrate 100. As depicted in FIGS. 7-8, one or more recesses 704 can be formed in the substrate 700. The recess 704 can be formed by forming a patterned photoresist 701 on the bulk semiconductor substrate 700, performing etching in the exposed regions of the substrate 700 and removing the photoresist. Although only a single recess 704 is illustrated for ease of understanding, several etches can be formed. For example, various depths can be created on different regions in the substrate by performing the photoresist formation, etching and removal process repeatedly to achieve desired height differences in fins. Here, the un-etched portions of the substrate can correspond to the highest fins, while the remaining depths corresponding to the heights of other fins. The differences in depths between any recesses 704 and the un-etched portions of the substrate denote the differences in fin heights of the multi-gate devices to be formed in the substrate 700.

As illustrated in FIG. 9, a hard mask 706 can be deposited on the surface of the substrate 700. The hard mask 706 can be composed of SiN, TiN, a carbon-based hard mask, or other materials that are typically used for hard masks. Indeed, the hard mask 706 can be composed of any materials that have an etch selectivity greater than one as compared to the substrate material. For example, if silicon is employed as the substrate 700, the hard mask 706 can be silicon dioxide, silicon nitride or spin-on-dielectric (SOD) or SiCN films. As provided in FIG. 10, fins 708 of various heights can be formed by etching the substrate 700 to a depth 710. For example, a patterned photoresist can be formed on the surface of the hard mask layer of the semiconductor substrate 700 to denote the positions of the fins. In addition, the exposed regions can be etched and the photoresist can be removed. The etching can be implemented via reactive ion etching. A typical etch gas that can be employed is a mixture of HBr and O₂ at a room temperature or a slightly higher temperature.

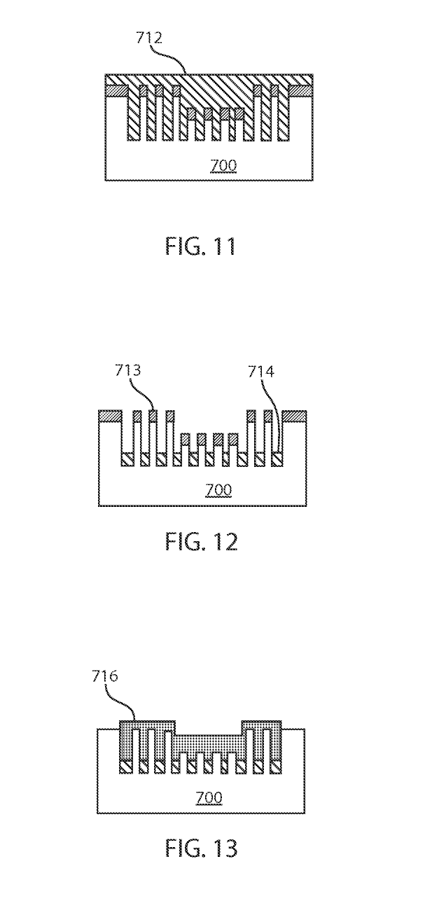

An STI (shallow trench isolation) oxide can be deposited on the resulting structure as shown in FIG. 11. For example, the STI oxide can be silicon dioxide. Here, in order to fill in the relatively small space between the fins, a chemic vapor deposition (CVD) type of oxide film can be employed. A TEOS (Tetraethyl orthosilicate)/Ozone precursor is preferred for the deposition. In addition, oxide regions 714 can be formed to isolate the various multi-gate devices, as illustrated in FIG. 12. Further, the hard masks 713 can be removed and a gate structure 716 can be formed over the fins 708, as illustrated in FIG. 13. In this example, a tri-gate structure is formed. However, it should be understood that although only one gate structure is shown in FIG. 10, other gate structures of the same or different material can be formed over other fins on the substrate (not shown) fabricated in accordance with this process. The gate structure 716 can include a high-dielectric constant (high-k) gate dielectric that overlays the fins 708 and a polysilicon material over the gate dielectric. This high-k gate can be contacted by various conductive materials to adjust its work function. To form source and drain regions in the device, the fins can be doped with appropriate p- or n-type dopants using a suitable doping process. For example, ion implantation can be employed to dope the fins. Thereafter, fabrication of the device can be completed. For example, contacts, vias, metal lines, and/or inter-layer dielectrics, etc. can be formed as is known in the art to complete the exemplary Trigate devices.

It should be noted, that in accordance with one advantageous aspect, the process illustrated in FIGS. 9-13 can be performed by implementing an essentially unmodified process that is designed or used for the fabrication of multi-gate devices with consistent fin heights. Here, as depicted in FIG. 10, although different fin heights are formed, the fin formation can still be implemented in a single step of the process, as in fabrication methods implemented to form fins with consistent heights. However, due to the preliminary etching steps, fins 708 of various heights are formed and each of the fins 708 forms a respective cohesive structure of semiconducting material with the substrate 700. Further, surfaces of the substrate 722 that border the fins are disposed at a same vertical position.

The device fabricated in accordance with FIGS. 6-13 can be included in an integrated circuit apparatus. For example, the devices can be implemented as devices 101, 108 and 110 in the portion of the circuit depicted in FIG. 1. In particular, the use of multiple fin heights can be employed to save circuit layout area space. For example, FinFET devices with essentially the same effective drive current as the devices in FIG. 2 can be implemented on a smaller layout area of FIG. 1 by configuring the devices 101 and 108 to have taller fin heights. Here, a FinFET can be fabricated to have an effective drive current that is 1.7 times greater than that of a planar device. In addition, use of variable fin heights can further ease manufacturing, as it permits the utilization of a periodic layout, where each FinFET device in at least a portion of a circuit can have the same circuit footprint, as illustrated in FIG. 1.

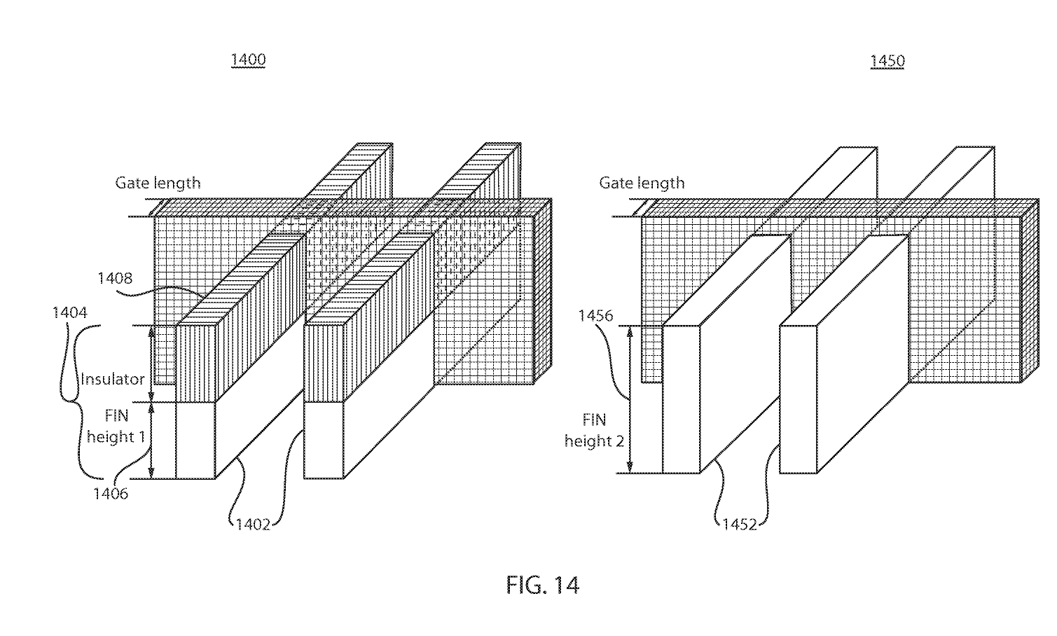

It should be further noted that, in other exemplary implementations, insulators can be added to the fins to maintain a consistent fin structure height, while utilizing different physical fin heights. For example, as illustrated in FIG. 14, a multi-gate device 1400 can have fins 1402 with a height 1406 that is smaller than the height 1456 of fins 1452 of the multi-gate device 1450. However, the addition of an insulator 1408 to the top of the fins 1402 renders the overall structure of the fins of the device 1400 to have a height 1404 that is consistent with (equal to) the height 1456 of the fins 1452 of the device 1450. Configuring the fins of various devices on an integrated circuit or a chip to have a consistent height of fin structures facilitates the formation of contacts, conductive lines and other elements of the circuit. To form the insulators 1408, a lithography patterning can be performed initially to define the separate areas for the devices 1400 and 1450. An etching is performed in the area designated for device 1400 to a depth corresponding to the thickness of the insulator 1408 to be formed on the fins of the device 1400. Further, the area for device 1400 can be back-filled with the insulator. Thereafter, the fin formation processes described above with regard to FIGS. 9 and 10 can be performed, where the etch is made to the depth 1404, which is the summation of the fin 1406 and the insulator 1408. Thereafter, the device 1400 and device 1450 with different fin heights are formed in accordance with the post-processing described above with regard to FIGS. 11-13.

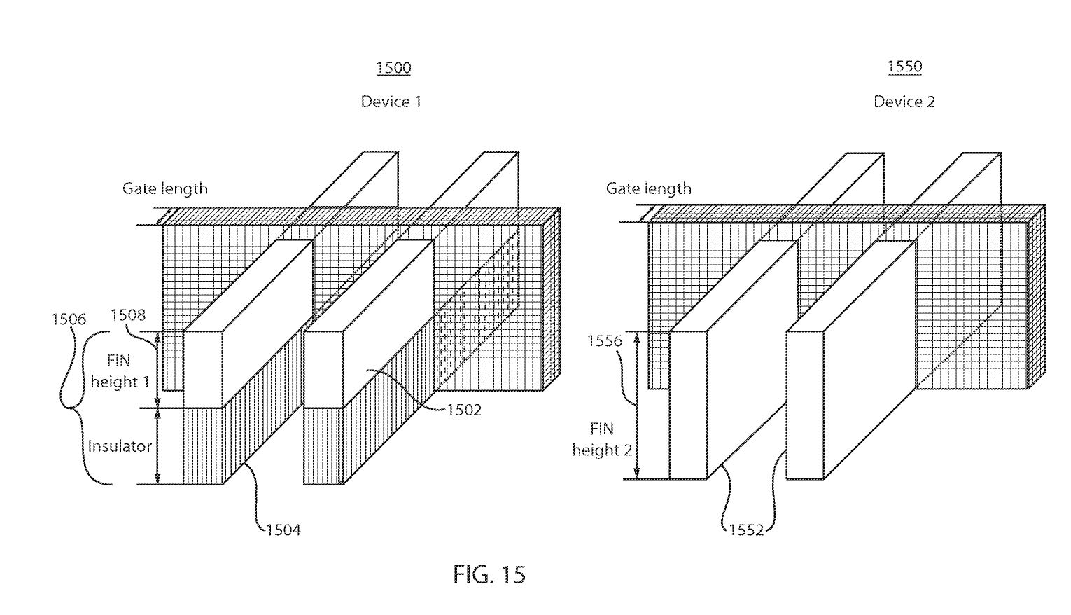

FIG. 15 illustrates an alternative implementation, where the fins 1502 of a multi-gate device 1500, which have a physical height 1508 that is smaller than the physical height 1556 of fins 1552 of another device 1550 on the same chip, are configured to have a fin structure height 1506 that is consistent with the height 1556 of fins 1552. However, here, the insulator 1504 is formed below the fins 1502. This configuration can be obtained through at least two different approaches. In accordance with the first approach, a lithography patterning is performed on the substrate to define the different areas for devices 1500 and 1550, respectively. An etch is performed to the depth of 1506 for the area designated for device 1500. The insulator is back filled in the area designated for device 1500 to a depth corresponding to the height of the insulator 1504 to be formed. The back filling can be followed by an epi-silicon (or other semiconductor) process to form the fins 1502 with a thickness of 1508. Thereafter, the fin formation processes described above with regard to FIGS. 9 and 10 can be performed, where the etch is made to the depth of 1506, which is the summation of the fin 1502 and the insulator 1504. Thereafter, the device 1500 and device 1550 with different fin heights are formed in accordance with the post-processing described above with regard to FIGS. 11-13. The second approach to forming the structures of devices 1500 and 1550 is as follows. The fins can be formed such that each of the fins for devices 1500 and 1550 have a consistent height. A lithography patterning can be employed to block the area designated for device 1550 and leave the area for device 1500 exposed. The region 1504 on which the insulator is formed can be doped with oxygen. The resistivity at region 1504 will be largely increased after a thermal anneal at, for example, 1000° C. at device 1500. In contrast to the fins 1402 of multi-gate device 1400, the fins 1502 of the multi-gate device 1500 do not form a cohesive structure of semiconducting material with the semiconductor substrate.

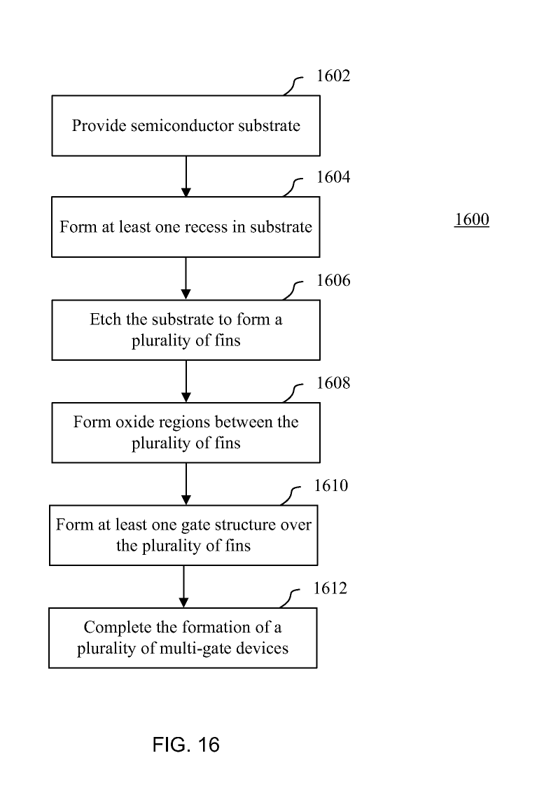

Referring now to FIG. 16, with continuing reference to FIGS. 6-13, a method 1600 for fabricating a circuit in accordance with an exemplary embodiment is illustrated. It should be note that the aspects of the present principles described above can be incorporated in and implemented in or by the method 1600. The method 1600 can begin at step 1602, at which a substrate composed of a semiconducting material can be provided. For example, as described above with respect to FIGS. 6-13, the semiconducting substrate can be a bulk semiconductor substrate.

At step 1604, at least one recess can be formed in the substrate. For example, one or more recesses can be formed by depositing a photoresist and performing appropriate etching, as described above with respect to FIGS. 7-8. As indicated above, a difference between a depth of recesses and a height of a highest surface of the substrate effects differences in height between fins of a plurality of fins to be formed in accordance with the method. For example, the difference between the depth of recess 704 and the un-etched surface of the substrate 700 in FIG. 8 denote the difference between the height of fins 718 and the height of fins 720. In addition, if multiple recesses are formed, the differences of the depths of any of the recesses similarly denote the differences in height of fins that are formed therefrom.

At step 1606, the substrate can be etched to form a plurality of fins. For example, as noted above with respect to FIGS. 9-10, the etching can involve forming a hard mask, depositing a photoresist and etching in exposed regions of substrate. As shown in FIG. 10, the fins 708 are directly on the substrate and form a respective cohesive structure of the semiconducting material with the substrate. Moreover, the fins 718 have a different height than the fins 720, thereby effecting different drive currents for fins 718 and fins 718. Moreover, as stated above, the formation of the fins can be implemented by performing a single etching step, after the recesses are formed to denote the different heights of various fins. For example, to save costs, this etching step can be part of a process with which a previous circuit with a periodic layout had been made. Furthermore, the circuit fabricated in accordance with the method 1600 can advantageously retain the same footprint as the previous circuit for certain multi-gate devices and, at the same time, have different electrical properties, such as drive current and capacitance, due to the height differences effected in the recess formation step(s) 1604. The performance of the etching in this manner and retaining the capability of using consistent-height processes can be exhibited by the structure of the fins. For example, the surfaces 722 of the substrate that border the fins of different heights are disposed at a same vertical position due to the implementation of a single etch to form the recesses. In contrast, methods that interrupt or inefficiently modify consistent-height methods by, for example, adding etching steps in the middle of the process, may exhibit fins that border surfaces of the substrate that are at different heights due to the additional etching steps.

At step 1608, oxide regions can be formed between the plurality of fins, for example, as described above with respect to FIGS. 11 and 12.

At step 1610, at least one gate structure can be formed over the plurality of fins, for example, as described above with respect to FIG. 13. As illustrated in FIG. 13, the gate structure 716 envelops a plurality of surfaces of the fins 708. At step 1612, the formation of a plurality of multi-gate devices can be completed. For example, as noted above, source and drain regions in the fins can be created by doping the fins using suitable doping processes. Here, the fins provide a channel between its respective source and its respective drain. Moreover, contacts, vias, metal lines, and/or inter-layer dielectrics, etc. can be formed as is known in the art to complete the exemplary multi-gate devices and the circuit on which they are fabricated.

It should also be noted that one or more other gate structures can be formed over substrate 700. For example, at steps 1604 and 1608 recesses and fins of different heights can be formed in another section of the substrate 700 that is not shown in FIGS. 6-13. Further, one or more other gate structures can be formed over these other fins. These other fins can all have consistent heights that are different from the heights of fins 708 or can have different heights between themselves. In addition, it should also be noted that the fins 708 can be constructed with a consistent height while the other fins (not shown) can also have a consistent height between themselves that is different from the height of fins 708. Moreover, a plurality of these gate structures and these fins can be formed in the same substrate 700. Steps 1608, 1610 and 1612 can also be performed with respect to these structures and fins to form multi-gate devices. On at least one part of the substrate, each of the multi-gate devices can be formed in accordance with a periodic circuit layout on a circuit 100, as illustrated in FIG. 1, above. In particular, multi-gate devices 101, 108 and 110 can each have fins with different heights but have the same areal dimensions and areal shape on a circuit layout of the circuit.

It should be further noted that the method may be modified to add an insulator 1408 to one or more of the fins, as described above with respect to FIG. 14. Here, the insulators can be added prior to the etching of step 1606 to ensure that the general fin structure of each of the fins 708 have a consistent height to facilitate electrical connections to conductive lines. For example, insulators 1408 can be formed on top of fins 718, where the height of the insulators 1408 are equal to the difference between the height of fins 720 and the height of fins 718.

Having described preferred embodiments of multi-gate field-effect transistors with variable fin heights and methods of fabrication (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1.-10. (canceled)

11. A method for fabricating a circuit apparatus comprising:
forming at least one recess in a substrate that is composed of a semiconducting material such that a difference between a depth of the at least one recess and a height of a surface of the substrate effects differences in height between fins of a plurality of fins;
etching the substrate to form the plurality of fins, wherein a first fin of the plurality of fins has a first height that is different from a second height of a second fin of the plurality of fins such that drive currents of the first and second fins are different, wherein the first and second fins form a respective cohesive structure of the semiconducting material with the substrate and wherein the surfaces of the substrate that border the first fin and the surfaces of the substrate that border the second fin are disposed at a same vertical position; and
forming a gate structure over a plurality of surfaces of a first subset of the plurality of fins.

12. The method of claim 11, wherein the etching is performed in a single step to form each of the fins in the first subset that are enveloped by the gate structure.

13. The method of claim 12, wherein the gate structure is a first gate structure and wherein the forming further comprises forming a second gate structure over a second subset of the plurality of fins.

14. The method of claim 13, wherein the first fin and the second fin are in the first subset of the plurality of fins.

15. The method of claim 13, wherein the first fin is in the first subset of the plurality of fins and wherein the second fin is in the second subset of the plurality of fins.

16. The method of claim 11, wherein the method further comprises:
forming a plurality of multi-gate devices, wherein the first fin is part of a first multi-gate device of the plurality of multi-gate devices, wherein the second fin is part of a second multi-gate device of the plurality of multi-gate devices and wherein the first and second multi-gate devices have the same areal dimensions and areal shape on a circuit layout of the circuit apparatus.

17. The method of claim 16, wherein the first multi-gate device and the second multi-gate device are part of a periodic layout on the circuit.

18. The method of claim 11, wherein the first height is smaller than the second height and wherein the device further comprises an insulator that is on the first fin and that has a height that is equal to the difference between the first height and the second height.

19. The method of claim 11, wherein the substrate is a bulk semiconductor substrate.

20. The method of claim 19, wherein the method further comprises:
forming oxide regions between the plurality of fins.
